(19) United States
(12) Patent Application Publication
(10) Pub. No.: US 2025/0169288 A1
(43) Pub. Date: May 22, 2025

(54) DISPLAY APPARATUS AND METHOD OF MANUFACTURING THE SAME

(71) Applicant: SAMSUNG DISPLAY CO., LTD., YONGIN-SI (KR)

(72) Inventors: Keunwoo Park, YONGIN-SI (KR); Jaecheol Park, YONGIN-SI (KR); Gakseok Lee, YONGIN-SI (KR); Donghan Kang, YONGIN-SI (KR); Shinhyuk Yang, YONGIN-SI (KR)

(21) Appl. No.: 18/778,606

(22) Filed: Jul. 19, 2024

(30) Foreign Application Priority Data
Nov. 20, 2023 (KR) 10-2023-0161449

(51) Int. Cl. H10K 59/122; H10K 59/12; H10K 59/123; H10K 59/80

(52) U.S. Cl. CPC H10K 59/122; H10K 59/1201; H10K 59/123; H10K 59/873

(57) ABSTRACT

A display apparatus includes a planarization layer disposed on a substrate and that includes a plurality of first regions and a second region, a plurality of pixel electrodes on the plurality of first regions of the planarization layer, a bank on the plurality of pixel electrodes and that includes a plurality of openings that respectively correspond to the plurality of pixel electrodes, first quantum dot layers in first openings of the plurality of openings of the bank, second quantum dot layers in second openings of the plurality of openings of the bank; and transmissive layers in remaining openings of the plurality of openings of the bank. A first distance from a top surface of the substrate to a top surface of the plurality of first regions is greater than a second distance from the top surface of the substrate to a top surface of the second region.

### CROSS-REFERENCE TO RELATED APPLICATION

This application claims priority under 35 U.S.C. § 119 from Korean Patent Application No. 10-2023-0161449, filed on Nov. 20, 2023 in the Korean Intellectual Property Office, the contents of which are herein incorporated by reference in their entirety.

### TECHNICAL FIELD

One or more embodiments are directed to a display apparatus and a method of manufacturing the same, and more particularly, to a display apparatus that can display a high-resolution image through structural modification, and a method of manufacturing the same.

### DISCUSSION OF THE RELATED ART

A display apparatus includes a plurality of pixels. For a full-color display apparatus, the plurality of pixels emit light of different colors. To this end, at least some pixels of the display apparatus have color converters. For example, at least some of the light generated by light-emitters of some pixels is converted into light of different colors by passing through the corresponding color converters and then propagating outside.

However, in a conventional display apparatus, color mixing can occur when implementing high-resolution products

### SUMMARY

One or more embodiments include a display apparatus with a increased color matching rate in a manufacturing process.

According to one or more embodiments, a display apparatus includes a substrate, a planarization layer disposed on the substrate and that includes a plurality of first regions and a second region outside the plurality of first regions, wherein a first distance from a top surface of the substrate to a top surface of each of the plurality of first regions is greater than a second distance from the top surface of the substrate to a top surface of the second region, a plurality of pixel electrodes disposed on the plurality of first regions of the planarization layer, a bank disposed above the plurality of pixel electrodes and that includes a plurality of openings that respectively correspond to the plurality of pixel electrodes, first quantum dot layers located within first openings of the plurality of openings of the bank, second quantum dot layers located within second openings of the plurality of openings of the bank, and transmissive layers located within remaining openings of the plurality of openings of the bank.

In an embodiment, when viewed in a plan view, the plurality of pixel electrodes are respectively located within the plurality of first regions.

In an embodiment, the display apparatus further includes a plurality of thin-film transistors (TFTs), wherein, when viewed in a plan view, the plurality of pixel electrodes are respectively electrically connected to the plurality of TFTs through contact holes located within the plurality of first regions.

In an embodiment, when viewed in a plan view, the plurality of pixel electrodes respectively extend outward from the plurality of first regions.

In an embodiment, the display apparatus further includes a plurality of TFTs, wherein, when viewed in a plan view, the plurality of pixel electrodes are respectively electrically connected to the plurality of TFTs through contact holes located outside the plurality of first regions.

In an embodiment, the display apparatus further includes a pixel defining layer disposed on the plurality of first regions and the second region of the planarization layer. The pixel defining layer covers edges of the plurality of pixel electrodes and includes penetration portions that expose central portions of the plurality of pixel electrodes.

In an embodiment, the pixel defining layer includes an additional penetration portion that overlaps the bank when viewed in a plan view.

In an embodiment, the display apparatus further includes an intermediate layer disposed on the plurality of pixel electrodes and that includes an emission layer, an opposite electrode disposed on the intermediate layer and that corresponds to the plurality of pixel electrodes, and an encapsulation layer disposed on the opposite electrode.

In an embodiment, a distance between top and bottom surfaces of the encapsulation layer in the additional penetration portion is greater than a distance between each of the plurality of pixel electrodes and a bottom surface of the bank.

In an embodiment, a distance between top and bottom surfaces of the encapsulation layer in the additional penetration portion is about 3.5 μm to about 4.0 μm.

In an embodiment, a distance between each of the plurality of pixel electrodes and a bottom surface of the bank is about 2.5 μm to about 3.0 μm.

In an embodiment, a distance between a top surface of the pixel defining layer and a bottom surface of the bank is about 2.0 μm to about 2.5 μm.

According to one or more embodiments, a method of manufacturing a display apparatus includes forming a planarization layer on a substrate. The planarization layer includes a plurality of first regions and a second region outside the plurality of first regions, where a first distance from a top surface of a substrate to a top surface of each of the plurality of first regions is greater than a second distance from the top surface of the substrate to a top surface of the second region. The method further includes forming a plurality of pixel electrodes on the plurality of first regions of the planarization layer, forming a bank that includes a plurality of openings that corresponds to the plurality of pixel electrodes, where the bank is disposed above the plurality of pixel electrodes, forming first quantum dot layers within first openings of the plurality of openings of the bank, forming second quantum dot layers within second openings of the plurality of openings in the bank, and forming transmissive layers within remaining openings of the plurality of openings of the bank.

In an embodiment, forming the plurality of pixel electrodes includes respectively forming the plurality of pixel electrodes within the plurality of first regions.

In an embodiment, forming the plurality of pixel electrodes further include extending the plurality of pixel electrodes outward from the plurality of first regions.

In an embodiment, the method further includes forming a pixel defining layer on the plurality of first regions and the second region of the planarization layer. The pixel defining layer covers edges of the plurality of pixel electrodes and includes penetration portions that expose central portions of the plurality of pixel electrodes.

In an embodiment, the method further includes forming an intermediate layer on the plurality of pixel electrodes, where the intermediate layer includes an emission layer, forming an opposite electrode on the intermediate layer, where the opposite electrode corresponds to the plurality of pixel electrodes, and forming an encapsulation layer on the opposite electrode. The bank is formed on the encapsulation layer.

In an embodiment, forming the pixel defining layer includes forming an additional penetration portion between the plurality of pixel electrodes, when viewed in a plan view.

In an embodiment, a distance between top and bottom surfaces of the encapsulation layer in the additional penetration portion is greater than a distance between each of the plurality of pixel electrodes and a bottom surface of the bank.

In an embodiment, a distance between the top and bottom surfaces of the encapsulation layer in the additional penetration portion is about 3.5 μm to about 4.0 μm.

### BRIEF DESCRIPTION OF THE DRAWINGS

FIG. 1 is a plan view of a display apparatus, according to an embodiment.

FIG. 2 is a plan view of a portion of a display apparatus, according to an embodiment.

FIG. 3 is a schematic cross-sectional view of a display apparatus of FIG. 2 taken along line B-B′ of FIG. 2, according to an embodiment.

FIG. 4 is a plan view of a portion of a display apparatus, according to an embodiment.

FIG. 5 is a schematic cross-sectional view of a display apparatus of FIG. 4 taken along line C-C′ of FIG. 4, according to an embodiment.

FIG. 6 is a schematic cross-sectional view of a display apparatus of FIG. 4 taken along line C-C′ of FIG. 4, according to an embodiment.

FIG. 7 is a cross-sectional view that illustrates effects, according to an embodiment.

FIG. 8 is a flow chart of a method of manufacturing a display apparatus, according to an embodiment.

### DETAILED DESCRIPTION

Reference will now be made in detail to embodiments, examples of which are illustrated in the accompanying drawings, wherein like reference numerals may refer to like elements throughout. In this regard, the present embodiments may have different forms and should not be construed as being limited to the descriptions set forth herein.

It will be understood that, when a layer, film, region, or plate is referred to as being “on” another element, the layer, film, region, or plate may be “directly on” the other element, and intervening elements may be present therebetween.

In the following embodiments, the x direction, the y direction, and the Z direction are not limited to directions along three axes of the orthogonal coordinate system and may be interpreted in a broader sense. For example, the x direction, the y direction, and the z direction may be perpendicular to one another, or may represent different directions that are not perpendicular to one another. In addition, a view from a direction, such as a z direction, perpendicular to a substrate that extends in an x direction and a y direction, is a plan view.

The term “about” as used herein is inclusive of the stated value and means within an acceptable range of deviation for the particular value as determined by one of ordinary skill in the art, considering the measurement in question and the error associated with measurement of the particular quantity, such as the limitations of the measurement system. For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art.

Hereinafter, embodiments will be described in detail with reference to the accompanying drawings. When describing embodiments with reference to the accompanying drawings, the same or corresponding elements may be denoted by the same reference numerals, and redundant descriptions thereof may be omitted or summarized.

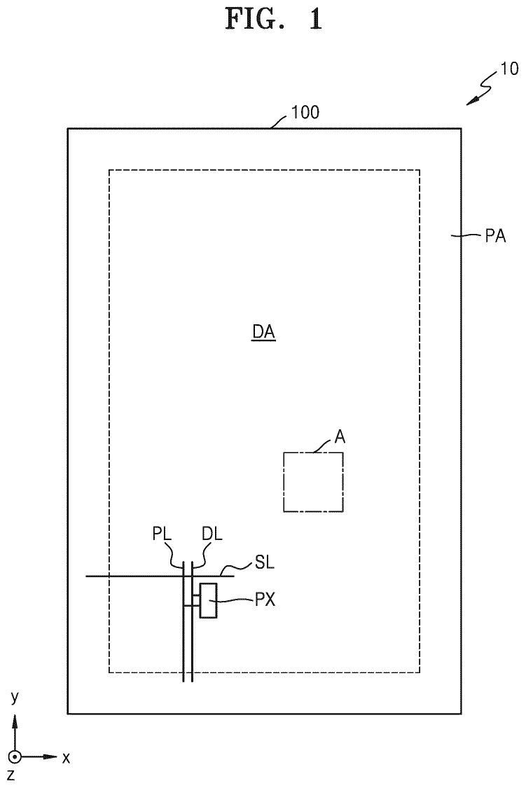

FIG. 1 is a plan view of a display apparatus according to an embodiment.

As illustrated in FIG. 1, a display apparatus according to an embodiment includes a display panel 10. The disclosure applies to any type of display apparatus as long as the display apparatus includes the display panel 10. Examples of the display apparatus include, for example, smartphones, tablets, laptops, televisions, or billboards.

The display panel 10 includes a display area DA and a peripheral area PA outside the display area DA. FIG. 1 shows that the display area DA has a rectangular shape. However, embodiments of the disclosure are not necessarily limited thereto. In other embodiments, the display area DA has other shapes, such as a circular shape, an elliptical shape, a polygonal shape, or a specific figure shape.

The display area DA is an area in which an image is displayed, and a plurality of pixels PX are disposed in the display area DA. Each of the pixels PX includes a display element, such as an organic light-emitting diode. The pixels PX emit, for example, red light, green light, or blue light. Each pixel PX is connected to a pixel circuit that includes a thin-film transistor (TFT), a storage capacitor, etc. The pixel circuit is connected to a scan line SL that transmits a scan signal to the pixel PX, a data line DL that crosses the scan line SL and transmits a data signal to the pixel PX, and a driving voltage line PL that supplies a driving voltage to the pixel PX. The scan line SL extends in an x direction and the data line DL and the driving voltage line PL extend in a y direction that crosses the x direction.

The pixel PX emits light having a luminance that corresponds to an electrical signal received from the pixel circuit electrically connected thereto. The display area DA displays an image through light emitted from the pixels PX. For reference, the pixel PX may be defined as an emission area in which one of red light, green light, or blue light is emitted, as described above.

The peripheral area PA is where no pixels PX are arranged, and thus, no image is displayed. Power supply lines that drive the pixels PX are disposed in the peripheral area PA. In addition, a terminal part to which a driver integrated circuit (IC) or a printed circuit board that includes a driving circuit is connected is disposed in the peripheral area PA.

For reference, because the display panel 10 includes a substrate 100, the substrate 100 also includes the display area DA and the peripheral area PA.

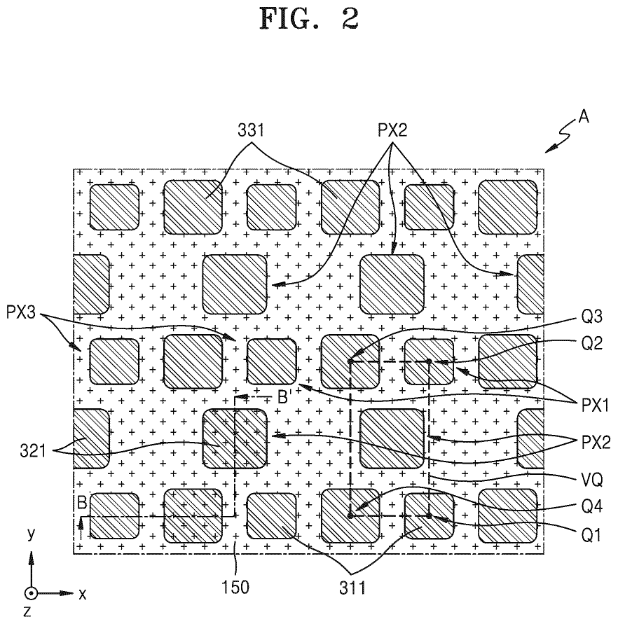

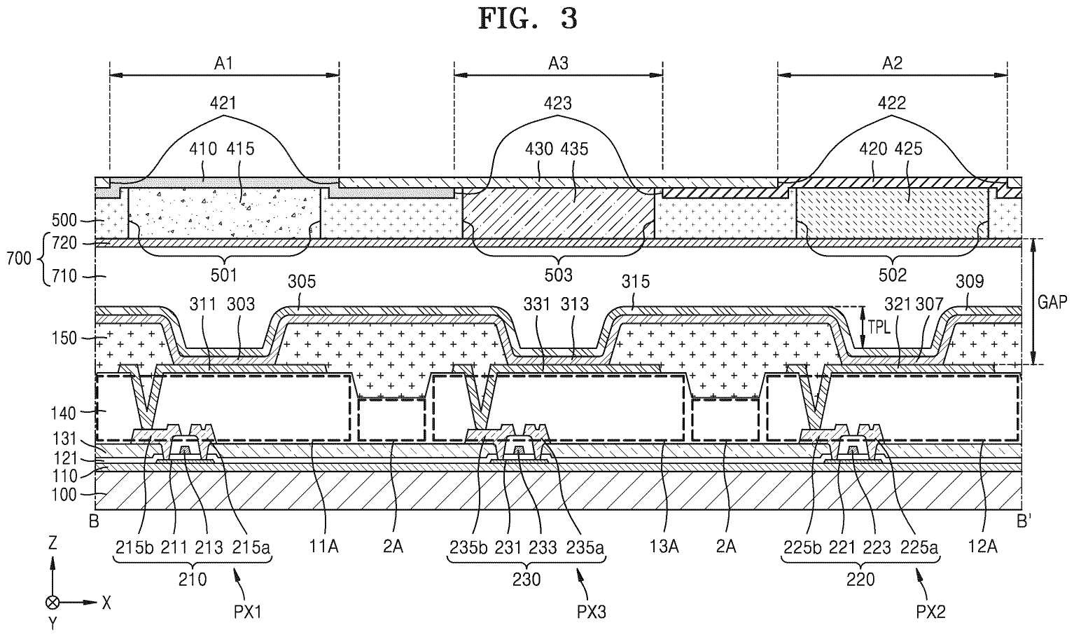

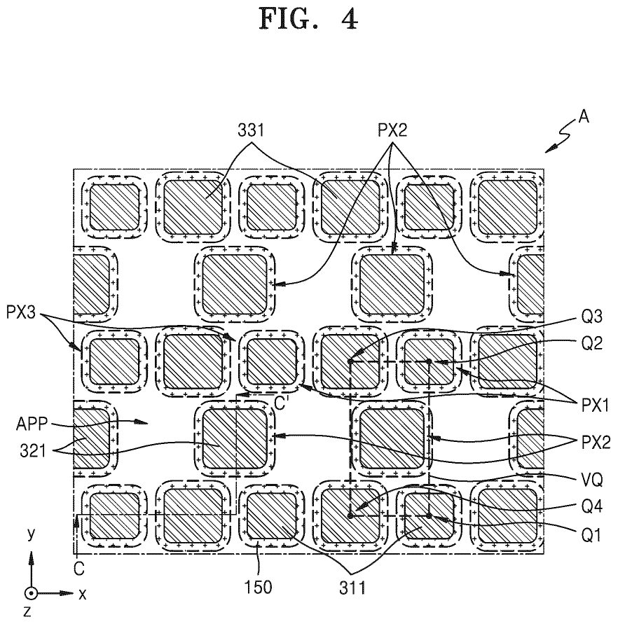

FIG. 2 is a plan view of a portion A of a display apparatus according to an embodiment, and FIG. 3 is a schematic cross-sectional view of a display apparatus of FIG. 2 taken along line B-B′ of FIG. 2, according to an embodiment. FIG. 4 is a plan view of a portion A of a display apparatus according to an embodiment. FIG. 2 may be an enlarged plan view of region A of FIG. 1. For reference, FIG. 2 illustrates first pixel electrodes 311, second pixel electrodes 321, and third pixel electrodes 331, and a pixel defining layer 150 that covers the edges of the first to third pixel electrodes 311 to 331. Because FIG. 4 is the same as or has some differences from the portion of the display apparatus illustrated in FIG. 2, the description of FIG. 4 focuses on differences from an embodiment of FIG. 2.

Referring to FIG. 2, in an embodiment, the display apparatus includes a plurality of pixels PX1, PX2, and PX3. The pixels PX1, PX2, and PX3 include a first pixel PX1, a second pixel PX2, and a third pixel PX3 that emit light of different colors. For example, the first pixel PX1 emit red light, the second pixel PX2 emit green light, and the third pixel PX3 emit blue light.

Each of the first pixel PX1, the second pixel PX2, and the third pixel PX3 has a polygonal shape when viewed from a direction (the z direction) perpendicular to the substrate 100, such as in a plan view. FIG. 2 shows that each of the first pixel PX1, the second pixel PX2, and the third pixel PX3 has a substantially rectangular shape, such as a rectangular shape with rounded corners, when viewed in a plan view. For example, a portion of each of the first pixel electrode 311 of the first pixel PX1, the second pixel electrode 321 of the second pixel PX2, and the third pixel electrode 331 of the third pixel PX3 that is exposed by the pixel defining layer 150, has a rectangular shape with rounded corners.

However, embodiments of the disclosure are not necessarily limited thereto. In some embodiments, a portion of each of the first pixel electrode 311 of the first pixel PX1, the second pixel electrode 321 of the second pixel PX2, and the third pixel electrode 331 of the third pixel PX3 that is exposed by the pixel defining layer 150 has one of a circular shape, an elliptical shape, or a polygonal shape other than a rectangular shape when viewed in a plan view. In some embodiments, a portion of each of the first pixel electrode 311 of the first pixel PX1, the second pixel electrode 321 of the second pixel PX2, and the third pixel electrode 331 of the third pixel PX3 that is exposed by the pixel defining layer 150 has a chamfered rectangular shape, such as an octagonal shape. For example, the chamfering of the edges thereof is different. For example, the lengths of the sides of the octagonal shape are not all equal to each other.

The sizes, such as the areas, of the first pixel PX1, the second pixel PX2, and the third pixel PX3, are different. For example, the area of the second pixel PX2 is greater than the area of the first pixel PX1 and the area of the third pixel PX3. The area of the first pixel PX1 is less than the area of the third pixel PX3.

The first pixel PX1 includes the first pixel electrode 311, the second pixel PX2 includes the second pixel electrode 321, and the third pixel PX3 includes the third pixel electrode 331. Referring to FIG. 2, the pixel defining layer 150 covers the edges of each of the first pixel electrode 311, the second pixel electrode 321, and the third pixel electrode 331. For example, the pixel defining layer 150 has an opening that exposes the central portion of the first pixel electrode 311, an opening that exposes the central portion of the second pixel electrode 321, and an opening that exposes the central portion of the third pixel electrode 331. The openings that expose the central portions of the pixel electrodes may be referred to as penetration portions. Referring to FIG. 4, when viewed in a plan view, the pixel defining layer 150 has an additional penetration portion APP between the pixel electrodes. Accordingly, compared to the pixel defining layer 150 illustrated in FIG. 2, an amount of material that forms the pixel defining layer 150 can be reduced, which reduces costs. In an embodiment, an intermediate layer and an opposite electrode of an organic light-emitting diode are disposed on the additional penetration portion APP.

The first pixel PX1, the second pixel PX2, and the third pixel PX3 are arranged as illustrated in FIG. 2. For example, considering a virtual rectangle VQ with a center that coincides with the center of the second pixel PX2, the first pixel PX1 is arranged at a first vertex Q1, and the first pixel PX1 is also arranged at a second vertex Q2 adjacent to the first vertex Q1 in a first direction (the y direction). In addition, the third pixel PX3 is arranged at a third vertex Q3 that is symmetrical to the first vertex Q1 with respect to the center of the virtual rectangle VQ, and the third pixel PX3 is also arranged at a fourth vertex Q4 that is symmetrical to the second vertex Q2 with respect to the center of the virtual rectangle VQ. The virtual rectangle VQ has a rectangular shape.

The first pixel PX1 and the third pixel PX3 are alternately arranged in a row that extends in the second direction (the x direction) that crosses the first direction (the y direction). In a row where the second pixel PX2 is located, only the second pixels PX2 are arranged in the second direction (the x direction). Pixels that emit light of the same color are arranged in the first direction (the y direction). Accordingly, a column of the first pixels PX1 that emit red light, a column of the second pixels PX2 that emit green light, and a column of the third pixels PX3 that emit blue light are alternately arranged in the second direction (the x direction).

In some embodiments, the first pixel PX1, the second pixel PX2, and the third pixel PX3 are arranged in a PENTILE form, a stripe form, a mosaic form, or an S-stripe form.

Referring to FIG. 3, a display apparatus according to an embodiment includes the substrate 100, also referred to as a lower substrate, the first pixel electrode 311, the second pixel electrode 321, and the third pixel electrode 331 that are disposed on the substrate 100, the pixel defining layer 150, and a bank 500.

The substrate 100 includes at least one of glass, a metal, or a polymer resin. The substrate 100 includes, for example, a polymer resin, such as one of polyethersulfone, polyacrylate, polyetherimide, polyethylene naphthalate, polyethylene terephthalate, polyphenylene sulfide, polyarylate, polyimide, polycarbonate, or cellulose acetate propionate. In some embodiments, other modifications are possible. For example, in some embodiments, the substrate 100 has a multilayer structure that includes two layers and a barrier layer therebetween, wherein the two layers include polymer resin and the barrier layer includes an inorganic material, such as silicon oxide, silicon nitride, or silicon oxynitride, etc.

The first pixel electrode 311, the second pixel electrode 321, and the third pixel electrode 331 are disposed on the substrate 100. In some embodiments, in addition to the first to third pixel electrodes 311 to 331, a first TFT 210, a second TFT 220, and a third TFT 230 that are electrically connected thereto are disposed on the substrate 100. For example, as illustrated in FIG. 3, the first pixel electrode 311 is electrically connected to the first TFT 210, the second pixel electrode 321 is electrically connected to the second TFT 220, and the third pixel electrode 331 is electrically connected to the third TFT 230. The first pixel electrode 311, the second pixel electrode 321, and the third pixel electrode 331 are disposed on a planarization layer 140 to be described below and that is disposed on the substrate 100.

The first TFT 210 include a first semiconductor layer 211, a first gate electrode 213, a first source electrode 215a, and a first drain electrode 215b. The first semiconductor layer 211 includes one of amorphous silicon, polycrystalline silicon, an organic semiconductor material, or an oxide semiconductor material. The first gate electrode 213 includes one or more various conductive materials and may have various layered structures. In an embodiment, the first gate electrode 213 includes a Mo layer and an Al layer. For example, the first gate electrode 213 has a layered structure of Mo/Al/Mo. In an embodiment, the first gate electrode 213 includes a TiNₓ layer, an Al layer, and/or a Ti layer. Each of the first source electrode 215a and the first drain electrode 215b also includes one or more of various conductive materials and have various layered structures. For example, each of the first source electrode 215a and the first drain electrode 215b includes a Ti layer, an Al layer, and/or a Cu layer. For example, each of the first source electrode 215a and the first drain electrode 215b has a layered structure of Ti/Al/Ti.

To electrically insulate the first semiconductor layer 211 from the first gate electrode 213, a gate insulating layer 121 that includes an inorganic material, such as at least one of silicon oxide, silicon nitride, and/or silicon oxynitride, is disposed between the first semiconductor layer 211 and the first gate electrode 213. In addition, an interlayer insulating layer 131 that includes an inorganic material, such as at least one of silicon oxide, silicon nitride, and/or silicon oxynitride, is disposed above the first gate electrode 213. The first source electrode 215a and the first drain electrode 215b are disposed on the interlayer insulating layer 131. An insulating layer that includes the inorganic materials described above, such as the gate insulating layer 121 and the interlayer insulating layer 131, may be formed by chemical vapor deposition (CVD) or atomic layer deposition (ALD). The same applies to embodiments and modifications to be described below.

A buffer layer 110 that includes an inorganic material, such as at least one of silicon oxide, silicon nitride, and/or silicon oxynitride, is disposed between the substrate 100 and the first TFT 210. The buffer layer 110 increases the smoothness of the top surface of the substrate 100, and can prevent or minimize infiltration of impurities from the substrate 100, etc., into the first semiconductor layer 211 of the first TFT 210.

The second TFT 220, which is located in the second pixel PX2, includes a second semiconductor layer 221, a second gate electrode 223, a second source electrode 225a, and a second drain electrode 225b. The third TFT 230, which is located in the third pixel PX3, includes a third semiconductor layer 231, a third gate electrode 233, a third source electrode 235a, and a third drain electrode 235b. Because the structure of the second TFT 220 and the structure of the third TFT 230 are the same as or similar to the structure of the first TFT 210 located in the first pixel PX1, repeated descriptions thereof are omitted.

The planarization layer 140 is disposed on the first TFT 210. For example, when an organic light-emitting device that includes the first pixel electrode 311 is disposed on the first TFT 210, as illustrated in FIG. 3, the planarization layer 140 substantially planarizes an upper portion of a protective layer that covers the first TFT 210. The planarization layer 140 includes, for example, an organic material, such as one of acryl, benzocyclobutene (BCB), or hexamethyldisiloxane (HMDSO).

The organic light-emitting device that includes the first pixel electrode 311, an intermediate layer 303 that includes an emission layer on the first pixel electrode 311, and an opposite electrode 305 on the intermediate layer 303 is located in the first pixel PX1. As illustrated in FIG. 3, the first pixel electrode 311 is in contact with one of the first source electrode 215a or the first drain electrode 215b through a contact hole formed in the planarization layer 140, etc., and is electrically connected to the first TFT 210. The first pixel electrode 311 includes a transmissive conductive layer that includes a transmissive conductive oxide, such as at least one of indium tin oxide (ITO), In₂O₃, or indium zinc oxide (IZO), and a reflective layer that includes a metal, such as one of Al or Ag. For example, the first pixel electrode 311 has a three-layer structure of ITO/Ag/ITO.

An organic light-emitting device that includes a second pixel electrode 321, an intermediate layer 303 that includes an emission layer on the second pixel electrode 321, and an opposite electrode 305 on the intermediate layer 303 is located in the second pixel PX2. In addition, an organic light-emitting device that includes a third pixel electrode 331, an intermediate layer 303 that includes an emission layer on the third pixel electrode 331, and an opposite electrode 305 on the intermediate layer 303 is located in the third pixel PX3. The second pixel electrode 321 is in contact with one of the second source electrode 225a or the second drain electrode 225b through a contact hole formed in the planarization layer 140, etc., and is electrically connected to the second TFT 220. The third pixel electrode 331 is in contact with one of the third source electrode 235a or the third drain electrode 235b through a contact hole formed in the planarization layer 140, etc., and is electrically connected to the third TFT 230. The description of the first pixel electrode 311 applies to the second pixel electrode 321 and the third pixel electrode 331.

As described above, the intermediate layer 303 that includes the emission layer is disposed on the second pixel electrode 321 of the second pixel PX2 and the third pixel electrode 331 of the third pixel PX3 as well as the first pixel electrode 311 of the first pixel PX1. The intermediate layer 303 has an integral shape across the first pixel electrode 311, the second pixel electrode 321, and the third pixel electrode 331. The intermediate layer 303 is patterned and disposed on the first pixel electrode 311, the second pixel electrode 321, and the third pixel electrode 331 as necessary. The intermediate layer 303 may include, in addition to the emission layer, one or more of a hole injection layer, a hole transport layer, and/or an electron transport layer as necessary. Some layers of the intermediate layer 303 have an integral shape across the first pixel electrode 311, the second pixel electrode 321, and the third pixel electrode 331, and other layers of the intermediate layer 303 are patterned and separately disposed on the first pixel electrode 311, the second pixel electrode 321, and the third pixel electrode 331. The emission layer in the intermediate layer 303 emits light of a wavelength in a first wavelength band. The first wavelength band is, for example, about 450 nm to about 495 nm.

The opposite electrode 305 disposed on the intermediate layer 303 also has an integral shape across the first to third pixel electrodes 311 to 331. The opposite electrode 305 includes a transmissive conductive layer that includes at least one of ITO, In₂O₃, or IZO, and also includes a semi-transmissive layer that includes a metal, such as at least one of Al, Li, Mg, Yb, or Ag. For example, the opposite electrode 305 is a semi-transmissive layer that includes one of MgAg, AgYb, Yb/MgAg, or Li/MgAg.

The pixel defining layer 150 is disposed on the planarization layer 140. The pixel defining layer 150 includes openings that respectively correspond to pixels. For example, the pixel defining layer 150 covers the edges of the first pixel electrode 311, the second pixel electrode 321, and the third pixel electrode 331 and has an opening that exposes the central portion of the first pixel electrode 311, an opening that exposes the central portion of the second pixel electrode 321, and an opening that exposes the central portion of the third pixel electrode 331. The opening that exposes the central portion of a pixel electrode may be referred to as a penetration portion. As described above, the pixel defining layer 150 defines a pixel. In addition, as illustrated in FIG. 3, the pixel defining layer 150 prevents an electric arc, etc., from occurring on the edges of the first pixel electrode 311, the second pixel electrode 321, and the third pixel electrode 331 by increasing the distance between the edge of each of the first to third pixel pixels 311 to 331 and the opposite electrode 305. The pixel defining layer 150 includes, for example, an organic material, such as polyimide or HMDSO.

In an embodiment, an encapsulation layer 700 includes an organic encapsulation layer 710 and an inorganic encapsulation layer 720. The organic encapsulation layer 710 is disposed on the opposite electrode 305 and the inorganic encapsulation layer 720 is disposed on the organic encapsulation layer 710. In addition, in another embodiment, a first inorganic encapsulation layer is disposed on the opposite electrode 305, an organic encapsulation layer is disposed on the first inorganic encapsulation layer, and a second inorganic encapsulation layer is disposed on the organic encapsulation layer. The organic encapsulation layer 710 includes a filler disposed between the bank 500 and the substrate 100. For example, in a display apparatus illustrated in FIG. 3, a filler fills a space between the inorganic encapsulation layer 720 and the opposite electrode 305. The filler includes a transmissive material. For example, the filler includes one of an acryl-based resin or an epoxy-based resin. In an embodiment, the encapsulation layer is a thin-film encapsulation layer. The organic encapsulation layer 710 planarizes the upper portion of the pixel defining layer 150. For example, when a distance TPL from the pixel electrodes to the top surface of the pixel defining layer 150 is about 1.5 μm, the organic encapsulation layer 710 has a thickness of about 3 μm to about 4 μm to planarize the upper portion of the pixel defining layer 150, and when the distance TPL from the pixel electrodes to the top surface of the pixel defining layer 150 is about 0.5 μm, the organic encapsulation layer 710 has a thickness of about 2.0 μm to about 2.5 μm to planarize the upper portion of the pixel defining layer 150. Accordingly, when the distance TPL from the pixel electrodes to the top surface of the pixel defining layer 150 is reduced, the thickness of the organic encapsulation layer 710 that planarizes the pixel defining layer 150 can also be reduced. A display apparatus according to an embodiment includes a planarization layer 140 in which the distance from the top surface of the substrate 100 to the top surface of each of a plurality of first regions 11A, 12A, and 13A is greater than the distance from the top surface of the substrate 100 to a second region 2A. For example, the planarization layer 140 may have a multilayer structure. Accordingly, the distance TPL from the pixel electrodes to the top surface of the pixel defining layer 150 is reduced by disposing pixel electrodes on the first regions 11A, 12A, and 13A of the planarization layer 140, and thus, the thickness of the organic encapsulation layer 710 that planarizes the pixel defining layer 150 may also be reduced. The thickness of the organic encapsulation layer 710 that planarizes the pixel defining layer 150 corresponds to the distance from the top surface of the pixel defining layer 150 to the bottom surface of the inorganic encapsulation layer 720. When the thickness of the organic encapsulation layer 710 is reduced, a distance GAP from the pixel electrodes to the bottom surface of the bank 500 is also reduced.

The bank 500 is disposed on the inorganic encapsulation layer 720. The bank 500 includes first openings 501, second openings 502, and third openings 503. The first opening 501 of the bank 500 corresponds to the opening of the pixel defining layer 150 that exposes the first pixel electrode 311, the second opening 502 of the bank 500 corresponds to the opening of the pixel defining layer 150 that exposes the second pixel electrode 321, and the third opening 503 of the bank 500 corresponds to the opening of the pixel defining layer 150 that exposes the third pixel electrode 331. For example, when viewed in a plan view, the first opening 501 of the bank 500 overlaps the opening of the pixel defining layer 150 that exposes the first pixel electrode 311, the second opening 502 of the bank 500 overlaps the opening of the pixel defining layer 150 that exposes the second pixel electrode 321, and the third opening 503 of the bank 500 overlaps the opening of the pixel defining layer 150 that exposes the third pixel electrode 331. Accordingly, when viewed in a plan view, the shape of the edge of each of the first to third openings 501 to 503 of the bank 500 is the same as or similar to the shape of the edge of the corresponding opening of the pixel defining layer 150. Accordingly, the first opening 501 of the bank 500 corresponds to the first pixel electrode 311, the second opening 502 of the bank 500 corresponds to the second pixel electrode 321, and the third opening 503 of the bank 500 corresponds to the third pixel electrode 331.

The bank 500 includes one or more of various materials. For example, the bank 500 includes an inorganic material, such as at least one of silicon oxide, silicon nitride, and/or silicon oxynitride. In an embodiment, the bank 500 further includes a photoresist material. The bank 500 can be formed by an exposure and development process that uses the photoresist material.

A first quantum dot layer 415 is disposed within the first openings 501 of the bank 500. The first quantum dot layer 415 overlaps the first pixel electrode 311 when viewed in a plan view. The first quantum dot layer 415 converts light having a wavelength in a first wavelength band that passes therethrough into light having a wavelength in a second wavelength band. In an embodiment second wavelength band is, for example, about 630 nm to about 780 nm. However, embodiments of the disclosure are not necessarily limited thereto. The wavelength band of the wavelength to be converted by the first quantum dot layer 415 and the wavelength band after conversion are modified in other embodiments.

The first quantum dot layer 415 includes quantum dots dispersed within a resin. In embodiments to be described below, a quantum dot is a crystal of a semiconductor compound and includes a material that can emit light of various emission wavelengths, depending on the size of the crystal. The diameter of the quantum dot is, for example, about 1 nm to about 10 nm.

Quantum dots may be synthesized by a wet chemical process, an organometallic chemical vapor deposition process, a molecular beam epitaxy process, or other processes similar thereto. A wet chemical process is a method of growing quantum dot particle crystals after mixing an organic solvent with a precursor material. In the wet chemical process, when crystals grow, the organic solvent acts as a dispersant coordinated to the surfaces of the quantum dot crystals and regulates the growth of the crystals. Accordingly, the wet chemical process is easier to perform than vapor deposition methods, such as metal organic chemical vapor deposition (MOCVD) or molecular beam epitaxy (MBE). In addition, the wet chemical process is a low-cost process and controls the growth of quantum dot particles.

The quantum dots include, for example, one or more of Group III-VI semiconductor compounds, Group II-VI semiconductor compounds, Group III-V semiconductor compounds, Group III-VI semiconductor compounds, Group I-III-VI semiconductor compounds, Group IV-VI semiconductor compounds, Group IV elements or compounds, or any combination thereof.

Examples of a Group III-VI semiconductor compound include binary compounds, such as In₂S₃, ternary compounds, such as AgInS, AgInS₂, CuInS, or CuInS₂, or any combination thereof.

Examples of a Group II-VI compound include binary compounds, such as CdS, CdSe, CdTe, ZnS, ZnSe, ZnTe, ZnO, HgS, HgSe, HgTe, MgSe, or MgS, ternary compounds, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, quaternary compounds, such as CdZnSeS, CdZnSeTe, CdZnSTe, CdHgSeS, CdHgSeTe, CdHgSTe, HgZnSeS, HgZnSeTe or HgZnSTe, or any combination thereof.

Examples of a Group III-V compound include binary compounds, such as GaN, GaP, GaAs, GaSb, AlN, AlP, AlAs, AlSb, InN, InP, InAs, or InSb, ternary compounds, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb, quaternary compounds, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, and any combination thereof. In some embodiments, the Group III-V semiconductor compounds further include Group II elements. Examples of a Group III-V semiconductor compound that further includes a Group II element include InZnP, InGaZnP, or InAlZnP.

Examples of a Group III-VI semiconductor compound include binary compounds, such as GaS, GaSe, Ga₂Se₃, GaTe, InS, InSe, In₂Se₃, or InTe, ternary compounds, such as InGaS₃ or InGaSe₃, or any combination thereof.

Examples of a Group I-III-VI semiconductor compound include ternary compounds, such as AgInS, AgInS₂, CuInS, CuInS₂, CuGaO₂, AgGaO₂, or AgAlO₂, or any combination thereof.

Examples of a Group IV-VI semiconductor compound include binary compounds, such as SnS, SnSe, SnTe, PbS, PbSe, or PbTe, ternary compounds, such as SnSeS, SnSeTe, SnSTe, PbSeS, PbSeTe, PbSTe, SnPbS, SnPbSe, or SnPbTe, quaternary compounds, such as SnPbSSe, SnPbSeTe, or SnPbSTe, or any combination thereof.

Examples of a Group IV element or compound include monatomic compounds, such as Si or Ge, binary compounds, such as SiC or SiGe, or any combination thereof.

Each of the elements included in the polyatomic compounds, such as the binary compounds, the ternary compounds, and the quaternary compounds, may be present in the particles at a uniform concentration or a non-uniform concentration.

In some embodiments, the quantum dots have a single structure. In some embodiments, the quantum dots have a core-shell dual structure in which the concentration of each of the elements in the quantum dots is uniform. For example, a material included in the core differs from a material in the shell. The shell of the quantum dot acts as a protective layer that maintains semiconductor properties by preventing chemical modification of the core and/or a charging layer that imparts electrophoretic properties to the quantum dots. The shell may be a single layer or include multiple layers. An interface between the core and the shell has a concentration gradient in which the concentration of the element present in the shell decreases toward the center thereof.

Examples of a compound of a shell of a quantum dot include a metal or non-metal oxide, a semiconductor compound, or any combination thereof. Examples of the metal or non-metal oxide include binary compounds, such as SiO₂, Al₂O₃, TiO₂, ZnO, MnO, Mn₂O₃, Mn₃O₄, CuO, FeO, Fe₂O₃, Fe₃O₄, CoO, CO₃O₄, or NiO, ternary compounds, such as MgAl₂O₄, CoFe₂O₄, NiFe₂O₄, or CoMn₂O₄, or any combination thereof. As described above, examples of a semiconductor compound include Group III-VI semiconductor compounds, Group II-VI semiconductor compounds, Group III-V semiconductor compounds, Group III-VI semiconductor compounds, Group 1-III-VI semiconductor compounds, Group IV-VI semiconductor compounds, or any combination thereof. Examples of a semiconductor compound include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

The quantum dots have a full width at half maximum (FWHM) of an emission wavelength spectrum in a range of about 45 nm or less, about 40 nm or less, or about 30 nm or less. In this range, color purity or color reproducibility is increased. Because light from the quantum dots is emitted in all directions, a viewing angle is increased.

In addition, the quantum dots include spherical, pyramidal, multi-armed, or cubic nanoparticles, nanotubes, nanowires, nanofibers, or nanoplatelet particles may be used.

Because the energy band gap can be controlled by adjusting the size of the quantum dots, light of various wavelengths can be obtained from the quantum dot emission layer. Therefore, a light-emitting device that emits light of various wavelengths can be implemented by using different sizes of quantum dots. For example, the size of the quantum dots can be selected to emit red light, green light, and/or blue light. In addition, the size of the quantum dots can be selected so that light of various colors can combine to emit white light.

The first quantum dot layer 415 includes a scatterer. By allowing incident light to be scattered by the scatterer in the first quantum dot layer 415, the incident light is efficiently converted by the quantum dots within the first quantum dot layer 415. The scatterer is not particularly limited as long as the scatterer can partially scatter transmitted light by forming an optical interface between the scatterer and the transmissive resin. For example, the scatterer includes metal oxide particles or organic particles. Examples of a metal oxide for the scatterer include titanium oxide (TiO₂), zirconium oxide (ZrO₂), aluminum oxide (Al₂O₃), indium oxide (In₂O₃), zinc oxide (ZnO), or tin oxide (SnO₂), and examples of an organic material for the scatterer include an acryl-based resin or an urethane-based resin. The scatterer scatters light in various directions regardless of the angle of incidence without substantially converting the wavelength of the incident light. Accordingly, the scatterer increases the side visibility of the display apparatus. In addition, the scatterer in the first quantum dot layer 415 increases light conversion efficiency by increasing the probability that light incident on the first quantum dot layer 415 will encounter the quantum dots.

The resin in the first quantum dot layer 415 can include any material that is transmissive and has excellent dispersion characteristics for the scatterer. For example, a polymer resin, such as one of an acryl-based resin, an imide-based resin, an epoxy-based resin, BCB, or HMDSO, can be used as a material of the first quantum dot layer 415. The material of the first quantum dot layer 415 can be formed by inkjet printing and is arranged in the first opening 501 of the bank 500 that overlaps the first pixel electrode 311.

A second quantum dot layer 425 is disposed within the second openings 502 of the bank 500. The second quantum dot layer 425 overlaps the second pixel electrode 321 when viewed in a plan view. The second quantum dot layer 425 converts light in a first wavelength band that passes therethrough into light in a third wavelength band. In an embodiment, the third wavelength band is, for example, about 495 nm to about 570 nm. However, embodiments of the disclosure are not necessarily limited thereto. The wavelength band of the wavelength to be converted by the second quantum dot layer 425 and the wavelength band after conversion belongs are modified in other embodiments.

The second quantum dot layer 425 includes quantum dots dispersed within a resin. In embodiments and modifications to be described below, the quantum dot refers to a crystal of a semiconductor compound and includes a material that can emit light of various emission wavelengths, depending on the size of the crystal. The diameter of the quantum dot is, for example, about 1 nm to about 10 nm. Because the description of the quantum dots in the first quantum dot layer 415 applies to the quantum dots in the second quantum dot layer 425, a repeated description of the quantum dots in the second quantum dot layer 425 is omitted.

The second quantum dot layer 425 includes a scatterer. By allowing incident light to be scattered by the scatterer in the second quantum dot layer 425, incident light is efficiently converted by the quantum dots within the second quantum dot layer 425. The scatterer is not particularly limited as long as the scatterer partially scatters transmitted light by forming an optical interface between the scatterer and the transmissive resin. For example, the scatterer includes metal oxide particles or organic particles. A metal oxide for the scatterer and an organic material for the scatterer are the same as those described above. The scatterer scatters light in various directions regardless of the angle of incidence without substantially converting the wavelength of the incident light. Accordingly, the scatterer increases the side visibility of the display apparatus. In addition, the scatterer in the second quantum dot layer 425 increases light conversion efficiency by increasing the probability that light incident on the second quantum dot layer 425 will encounter the quantum dots.

The resin in the second quantum dot layer 425 includes any material that is transmissive and has excellent dispersion characteristics for the scatterer. For example, a polymer resin, such as an acryl-based resin, an imide-based resin, an epoxy-based resin, BCB, or HMDSO, can be used as a material of the second quantum dot layer 425. The material of the second quantum dot layer 425 is formed by inkjet printing and arranged in the second opening 502 of the bank 500 that overlaps the second pixel electrode 321.

The third pixel PX3 emits through the openings light that have a wavelength in the first wavelength band that is generated in the intermediate layer 303, without wavelength conversion. Therefore, the third pixel PX3 does not have a quantum dot layer. Therefore, a transmission layer 435 that includes a transmissive resin is disposed in the third opening 503 of the bank 500 that overlaps the third pixel electrode 331. The transmission layer 435 includes at least one of acryl, BCB, or HMDSO. In addition, the transmission layer 435 also includes a scatterer. In some embodiments, unlike that illustrated in FIG. 3, the transmission layer 435 is omitted from the third opening 503 of the bank 500.

As described above, the first quantum dot layer 415 and the second quantum dot layer 425 are formed by inkjet printing. For example, the first quantum dot layer 415 and the second quantum dot layer 425 are formed by forming the bank 500 that has the first opening 501, the second opening 502, and the third opening 503 on the inorganic encapsulation layer 720, dotting a material for forming the first quantum dot layer 415 in the first opening 501 by inkjet printing, and dotting a material for forming the second quantum dot layer 425 in the second opening 502 by inkjet printing.

However, as illustrated in FIG. 3, a color filter layer is disposed on the first quantum dot layer 415, the second quantum dot layer 425, and the transmission layer 435. For example, a first color filter layer 410 is disposed on the first quantum dot layer 415, a second color filter layer 420 is disposed on the second quantum dot layer 425, and a third color filter layer 430 is disposed on the transmission layer 435. Each of the first color filter layer 410, the second color filter layer 420, and the third color filter layer 430 extends on both sides to cover the banks 500 adjacent on each side of the respective filter. The first color filter layer 410 passes light that has a wavelength that ranges from about 630 nm to about 780 nm. The second color filter layer 420 passes light that has a wavelength that ranges from about 450 nm to about 495 nm. The third color filter layer 430 passes light that has a wavelength that ranges from about 495 nm to about 570 nm.

The first to third color filter layers 410 to 430 increase the quality of displayed images by increasing the color purity of the emitted light. In addition, the first to third color filter layers 410 to 430 reduce external light reflection by lowering a rate at which external light incident on the display apparatus is reflected from the first to third pixel electrodes 311 to 331. A black matrix may be disposed between the first color filter layer 410 and the third color filter layer 430 as necessary.

The third color filter layer 430 has an opening 421 that defines an area for a first area A1 where it overlaps the first quantum dot layer 415. The first color filter layer 410 fills the opening 421, as illustrated in FIG. 3. In addition, the third color filter layer 430 has an opening 422 that defines an area for a second area A2 where it overlaps the second quantum dot layer 425. The second color filter layer 420 fills the opening 420, as illustrated in FIG. 3. The end of the first color filter layer 410 in the direction of the third opening 503 and the end of the second color filter layer 420 in the direction of the third opening 503 define an opening 423 that defines an area for a third area A3 where it overlaps the transmission layer 435. The opening 423 overlaps the third color filter layer 430.

In addition, a portion where the first color filter layer 410 and the third color filter layer 430 overlap each other, a portion where the second color filter layer 420 and the third color filter layer 430 overlap, each other, and a portion where the first color filter layer 410 and the second color filter layer 420 overlap each other serves the same role as the black matrix. For example, when the first color filter layer 410 passes only light having a wavelength ranging from about 630 nm to about 780 nm and the third color filter layer 430 passes only light having a wavelength ranging from about 450 nm to about 495 nm, in theory, there is no light that passes through both the first color filter layer 410 and the third color filter layer 430 where the first color filter layer 410 and the third color filter layer 430 overlap each other.

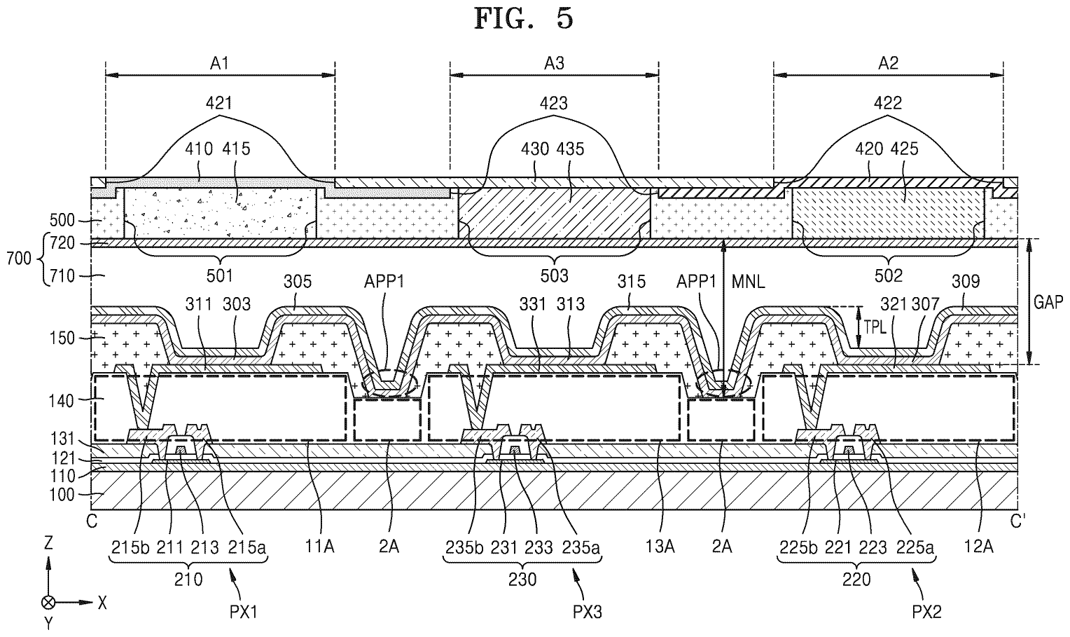

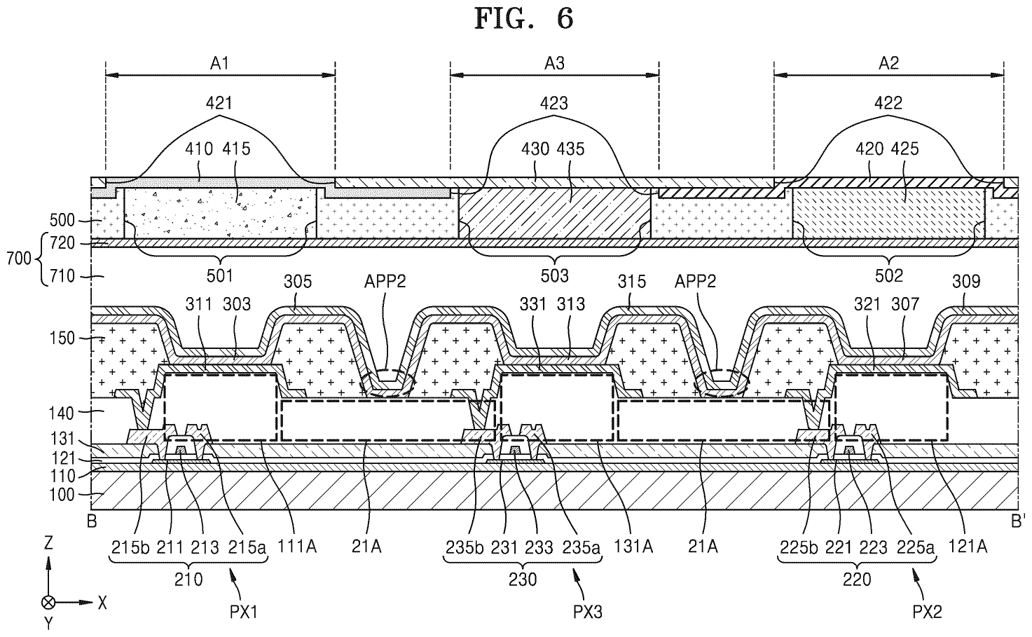

FIGS. 5 and 6 are schematic cross-sectional views of a display apparatus of FIG. 4 taken along line C-C′ of FIG. 4, according to an embodiment. Because the elements of a display apparatus illustrated in FIGS. 5 and 6 are the same as or similar to the elements of a display apparatus illustrated in FIG. 3, the following description focuses on the differences from a display apparatus illustrated in FIG. 3.

In an embodiment, FIG. 5 illustrates a planarization layer 140 in which the distance from a top surface of a substrate 100 to a top surface of each of a plurality of first regions 11A, 12A, and 13A is greater than the distance from a top surface of the substrate 100 to the second region 2A. The planarization layer 140 includes the first regions 11A, 12A, and 13A that are thicker than the surrounding second region 2A, and the second region 2A that is thinner than the first regions 11A, 12A, and 13A. For example, the planarization layer 140 has a stepped structure in which steps are formed so that the first regions 11A, 12A, and 13A are thicker than the second region 2A. In an example, the planarization layer 140 has a multilayer structure such that each of the first regions 11A, 12A, and 13A includes more layers than the second region 2A to form the stepped structure. A first pixel electrode 311, a second pixel electrode 321, and a third pixel electrode 331 are respectively disposed on the first regions 11A, 12A, and 13A. Accordingly, when viewed in a plan view, the first to third pixel electrodes 311, 321, and 331 are respectively located within the first regions 11A, 12A, and 13A. A first contact hole that electrically connects to a first TFT 210, a second contact hole that electrically connects to a second TFT 220, and a third contact hole that electrically connects to a third TFT 230 are respectively formed in the first regions 11A, 12A, and 13A of the planarization layer 140. Accordingly, the pixel electrodes disposed on the first regions 11A, 12A, and 13A can be patterned without interruption.

In an embodiment, FIG. 6 illustrates a planarization layer 140 in which the distance from a top surface of a substrate 100 to a top surface of each of a plurality of first regions 111A, 121A, and 131A is greater than the distance from a top surface of the substrate 100 to the second region 21A. The planarization layer 140 includes the first regions 111A, 121A, and 131A that are thicker than the surrounding second region 21A, and the second region 21A that is thinner than the first regions 111A, 121A, and 131A. For example, the planarization layer 140 has a stepped structure in which steps are formed so that the first regions 111A, 121A, and 131A are thicker than the second region 21A. In an example, the planarization layer 140 has a multilayer structure such that each of the first regions 111A, 121A, and 131A includes more layers than the second region 21A to form the stepped structure. A first pixel electrode 311, a second pixel electrode 321, and a third pixel electrode 331 are respectively disposed on portions of the first regions 111A, 121A, and 131A and portions of the second region 21A. Accordingly, when viewed in a plan view, the first to third pixel electrodes 311, 321, and 331 respectively extend outward from the first regions 111A, 121A, and 131A. A first contact hole that electrically connects to a first TFT 210, a second contact hole that electrically connects to a second TFT 220, and a third contact hole that electrical connects to a third TFT 230 are respectively formed in the second region 21A of the planarization layer 140.

Unlike an embodiment of FIG. 3, in embodiments of FIGS. 5 and 6, a pixel defining layer 150 further includes additional penetration portions APP1 and APP2 between the first pixel electrode 311, the second pixel electrode 321, and the third pixel electrode 331. The additional penetration portions APP1 and APP2 illustrated in FIGS. 5 and 6 are embodiments of the additional penetration portion APP illustrated in FIG. 4. When viewed in a plan view, the additional penetration portions APP1 and APP2 overlap the bank 500 between the pixel electrodes. A distance MNL between the top and bottom surfaces of the encapsulation layer in the additional penetration portions APP1 and APP2 is greater than a distance GAP between each of the pixel electrodes and the bottom surface of the bank 500. In an embodiment, the distance between each of the pixel electrodes and the bottom surface of the bank 500 is about 2.5 μm to about 3.0 μm.

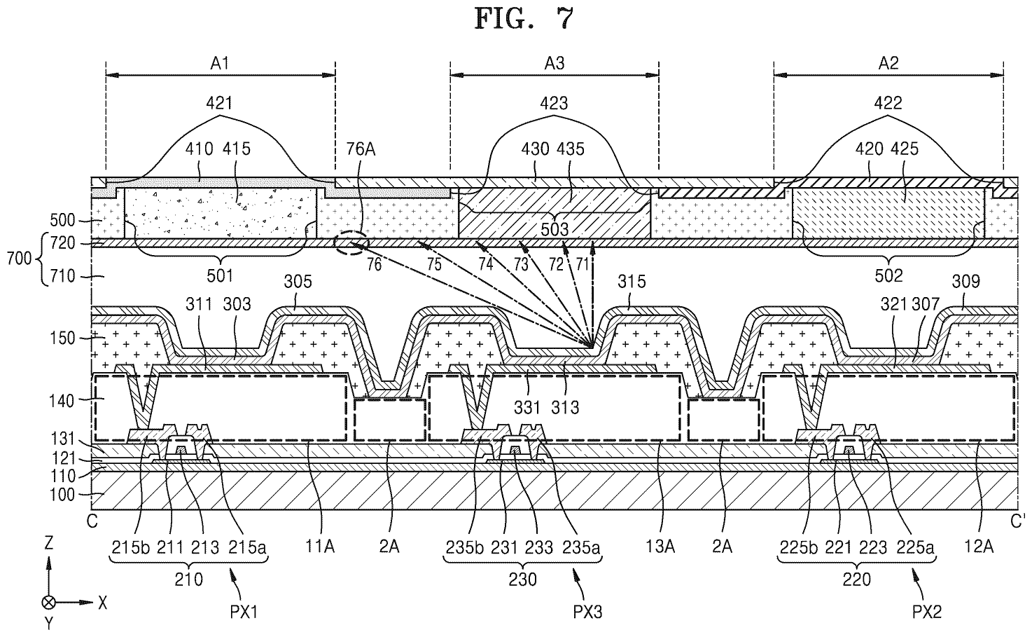

As illustrated in FIGS. 5 and 6, in some embodiments, a step is formed on the planarization layer 140, and the distance GAP between the pixel electrodes and the bottom surface of the bank 500 when the pixel electrodes are disposed on the plurality of first regions is shorter than when the pixel electrodes are disposed on the planarization layer 140 having a structure in which no step is formed. Because the pixel electrodes are closer to the bank 500 due to the steps formed on the first regions, the distance TPL from the pixel electrodes to the top surface of the pixel defining layer 150 is reduced, compared to a case where the planarization layer 140 is formed in un-stepped structure. For example, the distance from the top surface of the pixel defining layer 150 to the bottom surface of the bank 500 is also reduced. In an embodiment, the distance from the top surface of the pixel defining layer 150 to the bottom surface of the bank 500 is about 2.0 μm to about 2.5 μm. Because the distance from the top surface of the pixel defining layer 150 to the bottom surface of the bank 500 includes the thickness of the organic encapsulation layer 710 that planarizes the pixel defining layer 150, the distance MNL between the top and bottom surfaces of the encapsulation layer in the additional penetration portions APP1 and APP2 is also reduced when the distance from the top surface of the pixel defining layer 150 to the bottom surface of the bank 500 is reduced. When the planarization layer 140 is formed only in an un-stepped structure, the distance between the top and bottom surfaces of the encapsulation layer is equal to the distance between the pixel electrodes and the bottom surface of the bank 500. However, according to an embodiment, when some regions (the first regions) of the planarization layer 140 are relatively thick and the pixel electrodes are disposed on the first regions, the pixel electrodes are closer to the bank 500, and thus, the distance GAP between the pixel electrodes and the bottom surface of the bank 500 is reduced. Accordingly, the distance MNL between the top and bottom surfaces of the encapsulation layer 700 in the additional penetration portions APP1 and APP2 is greater than the distance between the pixel electrodes and the bank 500. The effects obtained when the distance GAP between the pixel electrodes and the bottom surface of the bank 500 is reduced is described with reference to FIG. 7.

FIG. 7 is a cross-sectional view that illustrates the effects according to an embodiment.

Referring to FIG. 7, in an embodiment, when the pixel electrodes are disposed on the first regions 11A, 12A, and 13A of the planarization layer 140, the distance GAP from the pixel electrodes to the bank 500 is reduced. Accordingly, light emitted from the third pixel PX3 includes light 71, 72, 73, and 74 emitted in a direction through the third openings 503, and light 75 and 76 emitted in a direction between the first openings 501 and third openings 503 within the bank 500, but not toward the first openings 501. For example, of light emitted from the third pixel PX3, light 76 has a maximum angle in the direction of the first openings 501 with respect to the direction (the +z direction) from the substrate 100 to the bank 500, and does not reach the first quantum dot layer 415, but reaches only the region 76A within bank 500, not the openings. Accordingly, the possibility that light emitted from the third pixel PX3 will mix with light emitted from the first pixel PX1 within the first quantum dot layer 415 is reduced, and the color matching rate of the display apparatus is increased. The above description applies to the first pixel PX1 and the third pixel PX3, and also applies to the first pixel PX1 and the second pixel PX2, and to the second pixel PX2 and the third pixel PX3.

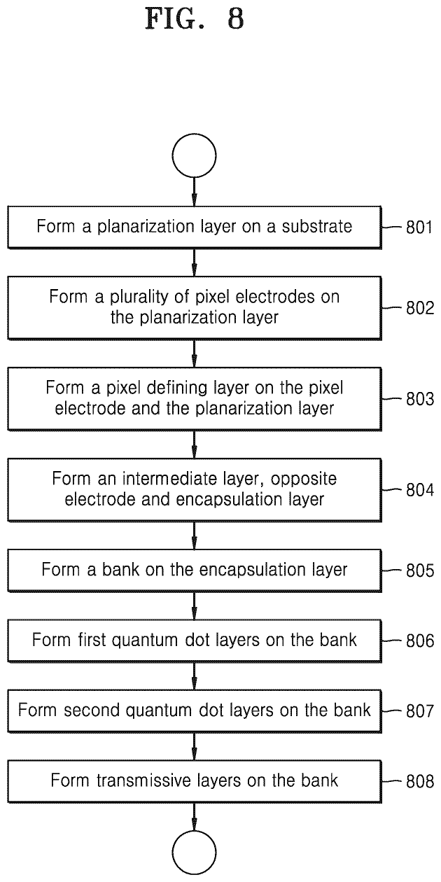

FIG. 8 is a flow chart of a method of manufacturing a display apparatus, according to an embodiment. Referring to the figure, the method begins by forming a planarization layer on a substrate at step 801. The planarization layer includes a plurality of first regions and a second region outside the plurality of first regions, and a first distance from a top surface of the substrate to a top surface of each of the plurality of first regions is greater than a second distance from the top surface of the substrate to a top surface of the second region. At step 802, a plurality of pixel electrodes are formed on the plurality of first regions of the planarization layer. In some embodiments, the plurality of pixel electrodes are formed within the plurality of first regions. In some embodiments, the plurality of pixel electrodes extend outward from the plurality of first regions. At step 803, a pixel defining layer is formed on the plurality of first regions and the second region of the planarization layer. The pixel defining layer covers edges of the plurality of pixel electrodes and includes penetration portions that expose central portions of the plurality of pixel electrodes. In some embodiments, forming the pixel defining layer further includes forming an additional penetration portion between the plurality of pixel electrodes when viewed a plan view. The method continues at step 804 by forming an intermediate layer that includes an emission layer on the plurality of pixel electrodes, forming an opposite electrode that corresponds to the plurality of pixel electrodes on the intermediate layer, and forming an encapsulation layer on the opposite electrode. At step 805, a bank is formed on the encapsulation layer and above the pixel electrodes. The bank includes a plurality of openings that correspond to the plurality of pixel electrodes. At step 806, first quantum dot layers are formed within first openings of the plurality of openings of the bank. At step 807, second quantum dot layers are formed within second openings of the plurality of openings in the bank, and at step 808, transmissive layers are formed within remaining openings of the plurality of openings of the bank.

According to one or more embodiments, a display apparatus is provided that has an increased color matching rate when implementing a high-resolution product.

The effects of embodiments of the disclosure are not limited to those described above, and other effects that are not mentioned herein will be clearly understood from the description of the claims by those of ordinary skill in the art.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus, comprising:
a substrate;
a planarization layer disposed on the substrate and that includes a plurality of first regions and a second region outside the plurality of first regions, wherein a first distance from a top surface of the substrate to a top surface of each of the plurality of first regions is greater than a second distance from the top surface of the substrate to a top surface of the second region;
a plurality of pixel electrodes disposed on the plurality of first regions of the planarization layer;
a bank disposed above the plurality of pixel electrodes and that includes a plurality of openings that respectively correspond to the plurality of pixel electrodes;
first quantum dot layers located within first openings of the plurality of openings of the bank;
second quantum dot layers located within second openings of the plurality of openings of the bank; and
transmissive layers located within remaining openings of the plurality of openings of the bank.

2. The display apparatus of claim 1, wherein, when viewed in a plan view, the plurality of pixel electrodes are respectively located within the plurality of first regions.

3. The display apparatus of claim 2, further comprising a plurality of thin-film transistors (TFTs),
wherein, when viewed in a plan view, the plurality of pixel electrodes are respectively electrically connected to the plurality of TFTs through contact holes located within the plurality of first regions.

4. The display apparatus of claim 1, wherein, when viewed in a plan view, the plurality of pixel electrodes respectively extend outward from the plurality of first regions.

5. The display apparatus of claim 4, further comprising a plurality of thin-film transistors (TFTs),
wherein, when viewed in a plan view, the plurality of pixel electrodes are respectively electrically connected to the plurality of TFTs through contact holes located outside the plurality of first regions.

6. The display apparatus of claim 1, further comprising a pixel defining layer disposed on the plurality of first regions and the second region of the planarization layer, wherein the pixel defining layer covers edges of the plurality of pixel electrodes and includes penetration portions that expose central portions of the plurality of pixel electrodes.

7. The display apparatus of claim 6, wherein the pixel defining layer includes an additional penetration portion that overlaps the bank when viewed in a plan view.

8. The display apparatus of claim 7, further comprising:
an intermediate layer disposed on the plurality of pixel electrodes and that includes an emission layer;
an opposite electrode disposed on the intermediate layer and that corresponds to the plurality of pixel electrodes; and
an encapsulation layer disposed on the opposite electrode.

9. The display apparatus of claim 8, wherein a distance between top and bottom surfaces of the encapsulation layer in the additional penetration portion is greater than a distance between each of the plurality of pixel electrodes and a bottom surface of the bank.

10. The display apparatus of claim 8, wherein a distance between top and bottom surfaces of the encapsulation layer in the additional penetration portion is about 3.5 μm to about 4.0 μm.

11. The display apparatus of claim 8, wherein a distance between each of the plurality of pixel electrodes and a bottom surface of the bank is about 2.5 μm to about 3.0 μm.

12. The display apparatus of claim 8, wherein a distance between a top surface of the pixel defining layer and a bottom surface of the bank is about 2.0 μm to about 2.5 μm.

13. A method of manufacturing a display apparatus, the method comprising:
forming a planarization layer on a substrate, wherein the planarization layer includes a plurality of first regions and a second region outside the plurality of first regions, wherein a first distance from a top surface of the substrate to a top surface of each of the plurality of first regions is greater than a second distance from the top surface of the substrate to a top surface of the second region;
forming a plurality of pixel electrodes on the plurality of first regions of the planarization layer;
forming a bank that includes a plurality of openings that correspond to the plurality of pixel electrodes, wherein the bank is disposed above the plurality of pixel electrodes;
forming first quantum dot layers within first openings of the plurality of openings of the bank;
forming second quantum dot layers within second openings of the plurality of openings in the bank; and
forming transmissive layers within remaining openings of the plurality of openings of the bank.

14. The method of claim 13, wherein forming the plurality of pixel electrodes comprises respectively forming the plurality of pixel electrodes within the plurality of first regions.

15. The method of claim 13, wherein forming the plurality of pixel electrodes further comprises extending the plurality of pixel electrodes outward from the plurality of first regions.

16. The method of claim 13, further comprising forming a pixel defining layer on the plurality of first regions and the second region of the planarization layer, wherein the pixel defining layer covers edges of the plurality of pixel electrodes and includes penetration portions that expose central portions of the plurality of pixel electrodes.

17. The method of claim 16, further comprising:
forming an intermediate layer on the plurality of pixel electrodes, wherein the intermediate layer includes an emission layer;
forming an opposite electrode on the intermediate layer, wherein the opposite electrode corresponds to the plurality of pixel electrodes; and
forming an encapsulation layer on the opposite electrode,
wherein the bank is formed on the encapsulation layer.

18. The method of claim 17, wherein forming the pixel defining layer further comprises forming an additional penetration portion between the plurality of pixel electrodes, when viewed a plan view.

19. The method of claim 18, wherein a distance between top and bottom surfaces of the encapsulation layer in the additional penetration portion is greater than a distance between each of the plurality of pixel electrodes and a bottom surface of the bank.

20. The method of claim 19, wherein a distance between the top and bottom surfaces of the encapsulation layer in the additional penetration portion is about 3.5 μm to about 4.0 μm.
